(19) United States
(12) Patent Application Publication
(10) Pub. No.: US 2020/0176622 A1
(43) Pub. Date: Jun. 4, 2020

(54) MASSIVELY CONNECTED INDIVIDUAL SOLAR CELLS

(71) Applicant: Higher Dimension Materials, Inc., Oakdale, MN (US)

(72) Inventors: Young-Hwa Kim, Hudson, WI (US); Richard D. Olmsted, Vadnais Heights, MN (US)

(21) Appl. No.: 16/623,303

(22) PCT Filed: Jun. 15, 2018
(86) PCT No.: PCT/US2018/037884

§ 371 Date: Dec. 16, 2019

Related U.S. Application Data
(60) Provisional application No. 62/521,037, filed on Jun. 16, 2017.
(60) Provisional application No. 62/560,524, filed on Sep. 19, 2017.
(60) Provisional application No. 62/571,714, filed on Oct. 12, 2017.
(60) Provisional application No. 62/587,887, filed on Nov. 17, 2017.
(60) Provisional application No. 62/595,830, filed on Dec. 7, 2017.
(60) Provisional application No. 62/598,270, filed on Dec. 13, 2017.
(60) Provisional application No. 62/619,510, filed on Jan. 19, 2018.

(51) Int. Cl. H01L 31/048; H01L 31/05; H01L 31/073; H01L 31/0749; H02S 30/10

(52) U.S. Cl. CPC H01L 31/0481; H01L 31/05; H02S 30/10; H01L 31/0749; H01L 31/073

(57) ABSTRACT

In some examples, an assembly including at least one vertical support; a plurality of Heliopanels affixed to the at least one vertical support, each Heliopanel of the plurality of Heliopanels including one or more substrates; a plurality of Heliocells affixed to the one or more substrates of the plurality of Heliopanels such that a plurality of continuous gaps is defined between adjacent Heliocells and wherein the gaps permit air, water and sunlight to pass through the Heliopanels, wherein each Heliocells of the plurality of Heliocells includes one or more solar cell units, and wherein the solar cell units are contained in one or more encapsulants to protect the solar cell units from one or more of water and oxygen molecules, atmospheric pollutants, dirt, soot, and strong chemicals or by mechanical abrasion, impact, UV light, or temperature; and electrical conductors interconnecting the Heliocells to each another to form an electrical circuit.

This application claims the benefit of U.S. Provisional Patent Application No. 62/521,037 filed Jun. 16, 2017; 62/560,524 filed Sep. 19, 2017; 62/571,714 filed Oct. 12, 2017; 62/587,887 filed Nov. 17, 2017; 62/595,830 filed Dec. 7, 2017; 62/598,270 filed Dec. 13, 2017; and 62/619,510 filed Jan. 19, 2018. The entire content of each of these applications in incorporated herein by reference.

### TECHNICAL FIELD

In some examples, the disclosure relates to assemblies of individually encapsulated solar cells of various types, where the individual cells are stable to environmental conditions of humidity, temperature, and UV radiation, and the individual cells are separated from one another by spaces.

### SUMMARY

The disclosure is directed to assemblies of individually encapsulated solar cells of various types, the individual cells are stable to environmental conditions, the individual cells are separated from one another by spaces, and methods for making and using the same. In some examples, the disclosure is directed to a 2-dimensional array of many solar cell units (SCU) which are encapsulated into solar cell capsules (SCC) made with materials which are impermeable to water and oxygen molecules, mechanically tough and impact resistant, and optically transparent, and environmentally harmless. A solar cell capsule (SCC) encapsulates a solar cell unit (SCU) such as a perovskite solar cell unit, a silicon wafer solar cell unit, or any other suitable solar cell construction, for strong protection of a SCU against any potential damages by water and oxygen molecules, atmospheric pollutants, dirt, soot, and strong chemicals or by mechanical abrasion, impact, and UV light.

A portion of or the entire surface area of a SCC may be optically transparent for admission of sunlight. A system or assembly of arrays of electrically interconnected SCCs built on a support structure that maintains a prescribed distance between adjacent SCUs is conveniently referred to as Massively Connected Solar Cells or MCSC for brevity. The size of an SCU may be chosen to be compatible with other specifications of the MCSC in an end-use application. For example, if individual solar cells are chosen to be silicon wafers, then an SCU would nominally be five inches or six inches across depending on the specific wafer size chosen. For other solar cell technologies, the size of an SCU may be dictated by other factors such as the optimum size to enable efficient and durable encapsulation. For example, new perovskite solar cells may be extremely sensitive to moisture (humidity), oxygen, and temperature. If any part of a perovskite cell is damaged, the damage quickly extends throughout the entire region of the cell destroying the whole cell. It may be advantageous, therefore, to limit the size of each individual cell so that damage is limited to a single cell and cannot extend through an entire module. Encapsulation of a small perovskite SCU inside of SCC which is, e.g., only one or a few two centimeters across or less improves effectiveness of encapsulation greatly. Encapsulation of a relatively large (e.g., one meter or larger) and rigid piece of mechanically fragile perovskite solar cell is extremely difficult and is expensive. With the MCSC, one can encapsulate small pieces of perovskite SCU easily and securely.

The spacing between SCCs may be determined by end-use specifications. In silicon wafer solar modules, the silicon wafers may be placed as close as possible to one another to maximize the total power per unit area and minimize the amount of other materials such as EVA encapsulant, glass covers, and framing materials. The close packing of such wafers to one another also reduces the land area or roof area required to generate a given amount of electrical power.

Sacrificing areal power efficiency by intentionally spacing SCCs apart from one another may provide for distinct advantages in some end uses. One such example application is to make flexible solar panels. An assembly of SCCs that are separated from one another and mounted on, e.g., a sheet or roll of a flexible substrate provides a flexible solar panel that can conform to surfaces with curvature. Such an assembly can be placed on top of many surfaces such as bus roofs, outdoor tents, on backpacks of hikers/soldiers, on curved roof tops and domes of buildings. These are just a few examples of uses of flexible solar modules and are not limitations on the present disclosure.

Unlike other rigid solar cell panels or flexible solar cell films, one can cut a large sheet or roll of MCSC into many smaller pieces and the small pieces of MCSC can be used to cover differently shaped or differently sized surfaces. Other flexible solar cell films are mechanically flimsy and difficult to cover rough or coarse surfaces or curved surfaces.

Another example feature of a flexible MCSC is that it may be built on a fabric, such as a woven fabric, which provides strong tensile strength and the fabric of MCSC can be glued to or attached to a variety of different surfaces such as roof tops or a wall of houses or top surface of buses, trucks, golf carts, even top surface of trains.

It can be easy to clean surface of MCSC and easy to get rid of dust on MCSC. One can even wash sheets of MCSC with soap and water if necessary.

Examples of MCSC may be durable and wear resistant. One can even step on the MCSC without damaging the MCSC, for instance, when one installs a large sheet or roll of MCSC on a roof. One can roll up a large sheet of MCSC into a compact roll for easy transportation or for hiking.

In some aspects, examples of the disclosure may overcome technical difficulties of making commercially viable perovskite solar cells, but other types of solar cells including conventional silicon-based solar cells can be incorporated into MCSC for highly versatile, flexible, and long-lasting solar cell sheets to rolls or sheets.

The solar cell assemblies may include pure or composite material single-layer or multi-layer substrates (e.g., woven, non-woven, needled, felted or knitted fabrics; films, meshes, or nets) wherein the layers may be the same or different from one another including a plurality of encapsulated solar cell units affixed to and separated by gaps on one or more surfaces of the substrate. The solar cells may be of various types such as, but not limited to, silicon wafers; perovskite-based solar cells having n-type semiconductors, electron transport layer (ETL); p-type semiconductors, hole transport layer (HTL); both n-type and p-type semiconductors; or solar cells of various thin-film constructions such as CdTe, copper indium gallium diselenide (CIGS) solar cells, or a hybrid structure that incorporates single crystal silicon, of the type used in silicon solar cells, together with the perovskite structure or other solar cell material. In some examples, a key feature of the MCSC is that it is not limited to specific solar cell technologies, it is intended to be applicable to most if not all such constructions.

Regardless of the specific solar cell technology used in the MCSC, the flexible solar module examples may share the general properties of being sufficiently flexible to conform to surfaces of low to moderate curvature and being constructed from a massively interconnected network of individual independent solar cell capsules.

Another example where sacrificing areal power efficiency by intentionally spacing SCCs apart from one another has distinct advantages is in producing solar panels that have an effective porosity that reduces wind loading, increases cooling, and reduces areal weight density and allows the passage of sunlight through the solar panel. Spacing SCCs apart from one another on a porous mesh, net, screen, or lattice allows free air flow between and about SCC units. It also may allow sunlight to penetrate the panel and reach the ground behind the panel. Problems solved by the porous nature of some examples of the disclosure include overheating of solar panels, loss of cultivated land, and environmental damage associated with traditional solar farms.

In one aspect, the disclosure relates to a solar cell assembly comprising at least one substrate including a top surface; a plurality of solar cell capsules affixed to the top surface of the at least one substrate such that a plurality of continuous gaps is defined between adjacent solar cell capsules of the plurality of solar cell capsules; one or more solar cell units contained in at least one of the plurality of solar cell capsules, wherein the solar cell units are contained in an encapsulant to protect the solar cell units from one or more of water and oxygen molecules, atmospheric pollutants, dirt, soot, and strong chemicals or by mechanical abrasion, impact, UV light, and temperature; and a plurality of electrical conductors interconnecting the solar cell capsules one to another to form an electrical circuit.

In another aspect, the disclosure relates to a method comprising forming a solar cell assembly, the solar cell assembly comprising at least one substrate including a top surface; a plurality of solar cell capsules affixed to the top surface of the at least one substrate such that a plurality of continuous gaps is defined between adjacent solar cell capsules of the plurality of solar cell capsules, wherein each of solar cell capsules of the plurality of solar cell capsules includes one or more solar cell units, wherein the one or more solar cell units are contained in an encapsulant to protect the solar cell units from one or more of water and oxygen molecules, atmospheric pollutants, dirt, soot, and strong chemicals or by mechanical abrasion, impact, UV light, and temperature; and a plurality of electrical conductors interconnecting the solar cell capsules one to another to form an electrical circuit.

This summary is intended to provide an overview of the subject matter described in this disclosure. It is not intended to provide an exclusive or exhaustive explanation of the assemblies and methods described in detail within the accompanying drawings and description below. Further details of one or more examples are set forth in the accompanying drawings and the description below. Other features, objects, and advantages will be apparent from the description and drawings, and from the statements provided below. The disclosure is not limited by the embodiments that are described herein. These embodiments serve only to exemplify aspects of the disclosure.

### BRIEF DESCRIPTION OF DRAWINGS

The following drawings are illustrative of example embodiments and do not limit the scope of the disclosure. The drawings are not to scale (unless so stated) and are intended for use in conjunction with the explanations in the following detailed description. Examples will hereinafter be described in conjunction with the appended drawings wherein like numerals denote like elements.

FIG. 1a is a conceptual diagram illustrating a side view of an example single encapsulated SCC unit as defined and described in the disclosure.

FIG. 1b is a conceptual diagram illustrating a top-down view of the single encapsulated SCC unit of FIG. 1a.

FIG. 2 is a conceptual diagram illustrating an example flexible MCSC assembly in accordance with some examples of the disclosure. As described below, the MCSC assembly may include an array of SCC units affixed to a substrate with spaces between adjacent SCC units, where the SCC units are electrically interconnected to form an electrical circuit.

FIG. 3 is a conceptual diagram illustrating another example MCSC including an array of SCCs affixed to a substrate with spaces between adjacent SCC units. As described below, the SCC units are electrically interconnected to form an electrical circuit. The substrate may be a lattice or scaffold comprised of a frame surrounding support rods or bars. The space between adjacent SCC units determines the effective porosity of the MCSC assembly.

FIGS. 4a and 4b are conceptual diagrams illustrating another example MCSC including an array of SCCs affixed to a substrate with spaces between adjacent SCC units. In the example, the substrate is a mesh or net. As described below, the space between adjacent SCC units determines the effective porosity of the MCSC assembly. The mesh or net is advantageous as it allows the spaces to be adjusted without changing the substrate mesh or net structure.

FIGS. 5a, 5b, and 5c are conceptual diagrams illustrating how the frame and support members of an MCSC assembly can be combined with SCC base layer encapsulant with top layer transparent encapsulants used to complete the encapsulation of the individual SCC units.

### DETAILED DESCRIPTION

In some instances, silicon wafer solar panels are generally large with dimensions measured in meters and are constructed as follows from bottom (side away from sunlight) to top. At the bottom is a backsheet layer commonly of a material such as a polyvinyl fluoride film. A specific example of such a film is TEDLAR® which is produced by the E. I. du Pont de Nemours and Company or its affiliates.

The backsheet needs to be durable to weathering, prevent penetration by water, be lightweight, and be able to reflect light off its top surface. The next layer is commonly an encapsulating material such as EVA, ethyl vinyl acetate, that both seals the panel against the elements, and serves as a lubricating layer that allows materials adjacent to one another with different coefficients of thermal expansion to slide against one another during temperature changes. Next comes an array of silicon wafers. The wafers are generally arranged in periodic arrays that allow wafers to be strung together with electrically conducting tabbing material to make the requisite electrical circuits to deliver specified voltage and currents from the panel. The wafers are arranged to maximize the areal coverage of the panel surface by wafers thus generating the most electrical power for given surface area. The wafers are covered by another layer of EVA. The top of the panel is most often glass, nominally 4 mm thick. The glass provides the overall strength of the module in addition to permitting sunlight to impinge on the silicon wafer solar cells. This entire stacked assembly is surrounded by an aluminum frame and all interfaces of the layers are sealed with various sealers and tapes to isolate the interior of the panel from the environment.

The resultant panel is large, heavy, rigid, and does not allow sunlight, air, or water to pass through the panel.

These characteristics of traditional silicon wafer solar panels strongly constrain where they can be installed, force large costs to be incurred in their support structures, and damage the environment.

The specific problems addressed by some examples of the disclosure are rigidity that prevents solar panels from conforming to surfaces with curvature, excessive weight and wind loading (no air passage through panel) that require major changes to building structures for roof installed solar panels, and damage to local eco systems where solar panels are installed.

In some embodiments, the disclosure relates to solar cell assemblies of various types that are sufficiently flexible to conform to surfaces and are stable to environmental conditions of humidity, temperature, and UV radiation.

An example solar cell assembly may consist, consist essentially of, or comprise a plurality of self-contained solar cell capsules, SCC, affixed to a flexible substrate, with SCCs separated from one another by a prescribed distance maintained by the attachment of the SCCs to the flexible substrate, and the SCCs interconnected to one another by a network of electrical conductors. A self-contained solar cell unit that converts light to electricity is called a Solar Cell Unit, SCU. To protect SCUs from environmental conditions such as humidity and oxygen, the individual SCUs may be encapsulated by materials that are impervious to water, oxygen and other contaminants yet permit the entry of light on at least one surface to energize the SCU and produce electricity. Such an encapsulating material may be referred to herein as a Transparent Protective Material (TPM). An SCU totally encapsulated by TPM may be referred to herein as a Solar Cell Capsule (SCC). The full assembly of SCUs interconnected together in an electrically parallel fashion may be referred to herein as a Massively Connected Solar Cell (MCSC).

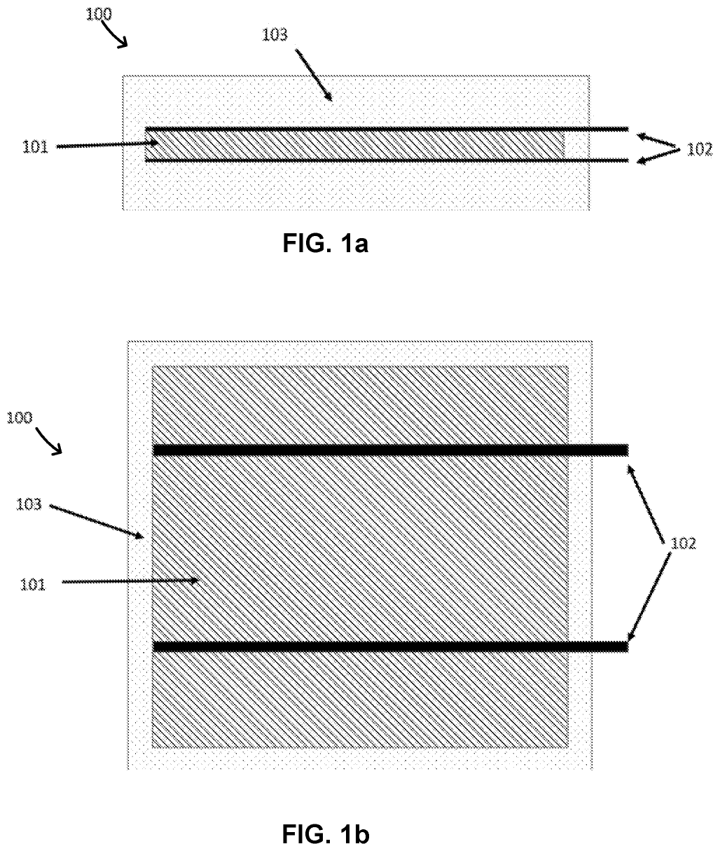

An example of a single SCC unit in accordance with the disclosure is shown in FIGS. 1a and 1b. FIG. 1a is a conceptual diagram illustrating a side view of the SCC 100 and FIG. 1b is a conceptual diagram illustrating a top-down view of the SCC 100. In this example, the SCC 100 includes of a silicon wafer 101 totally encapsulated in a suitable material 103. The silicon wafer 101 constitutes the SCU of the SCC unit. Electrically conducting tabbing material 102 is electrically coupled to silicon wafer and may define an anode and cathode, e.g., on either side, for the silicon wafer SCU. Electrically conducting tabbing material 102 is shown to project to the exterior of the SCC 100 through encapsulating material 103 thus permitting the anode and cathode to be connected to other SCC units in the overall MCSC ensemble.

The encapsulating material 103 may be any suitable material that will isolate the wafer 101 from materials or conditions that may harm the wafer 101. One choice of the encapsulating material is an undiluted clear difunctional bisphenol A/epichlorohydrin derived liquid epoxy resin cross-linked or hardened with an aliphatic amine hardener. Such a hardener will prevent deterioration of the epoxy when it is exposed to UV radiation. The choice of such an epoxy as the encapsulant is not limiting and any material suitable to the application can be used. For example, the encapsulant may be chosen as a silicone rubber that has been prepared by a platinum catalyst synthetic route to avoid acetic acid contaminants that would corrode the encapsulated electrical connections. The encapsulant may also include more than one layer. In the case of the silicone rubber encapsulant one may sandwich the SCC inside layers of ETFE or PTFE film that are heat sealed to isolate the SCC from the environment. Such a structure may provide a self-cleaning action to atmospheric pollutants such as soot and pollens since the ETFE and PTFE are known to be strongly hydrophobic so water cannot wet them.

Any suitable technique may be used to form the example SCC of FIGS. 1a and 1b. One example technique to prepare the SCC 100 using the aforementioned epoxy material is to solder tabbing material to a silicon wafer to form the electrodes 102, prepare a mold from a material such as silicone rubber that the epoxy will not wet, then fill the mold with the epoxy material 103, insert the wafer 101 and electrodes 102 into the epoxy material 103 is such a manner to eliminate or substantially eliminate bubbles, and then cure the epoxy material 103. Since the epoxy does not wet the silicone rubber mold, the completed SCC can be easily removed from the mold once the epoxy has cured.

As described herein, in some examples, a plurality of individual SCCs (e.g., like SCC 100 shown in FIGS. 1a and 1b) may be attached to a substrate and electrically interconnected to form a MCSS. Any suitable substrate may be employed in such a MCSS. In some examples, the flexible substrate may be a flexible fabric substrate. The fabric substrate may be a knitted, woven, needled, felt, and/or non-woven fabric. The flexible substrate may be a single layer or multiple layer construction with the composition of each layer being the same or different than the composition of other layers. Each layer may be composed of a single component or be composed of multiple materials the proportion of each material to the others being determined by the ultimate purpose of the overall solar cell assembly. Flexible substrate layers may be bonded to one another, laminated to one another or integrally woven, knitted, felted, or needled together to form the flexible substrate.

In some examples, the flexible substrate may be a flexible film substrate. The flexible substrate may be a single layer or multiple layer construction with the composition of each layer being the same or different than the composition of other layers. Each layer may be composed of a single component or be composed of multiple materials the proportion of each material to the others being determined by the ultimate purpose of the overall solar cell assembly. Flexible substrate layers may be bonded to one another, laminated to one another to form the flexible substrate.

In some examples, the flexible substrate may be a flexible mesh substrate. The flexible substrate may be a single layer or multiple layer construction with the composition of each layer being the same or different than the composition of other layers. Each layer may be composed of a single component or be composed of multiple materials the proportion of each material to the others being determined by the ultimate purpose of the overall solar cell assembly. Flexible substrate layers may be bonded to one another, laminated to one another or integrally woven, knitted, felted, or needled together to form the flexible substrate. It is anticipated that a flexible mesh substrate may serve as the electrical conduction network of the MCSC for either the anode or the cathode. A two-layer mesh with the layers insulated from one another may serve as the electrical conduction networks for both the anode and the cathode.

In some examples, the flexible substrate may be a flexible net substrate. The difference between a mesh and a net is that in a mesh, points of overlap of two fibers are bonded to one another (though not necessarily all points of overlap are bonded) whereas in a net, points of overlap of two fibers are knotted in some fashion (though not necessarily all points of overlap are knotted) the knots may allow points of overlap to be either tight or loose. The flexible substrate may be a single layer or multiple layer construction with the composition of each layer being the same or different than the composition of other layers. Each layer may be composed of a single component or be composed of multiple materials the proportion of each material to the others being determined by the ultimate purpose of the overall solar cell assembly. Flexible substrate layers may be bonded to one another, laminated to one another or integrally woven, knitted, felted, or needled together to form the flexible substrate. It is anticipated that a flexible mesh substrate may serve as the electrical conduction network of the MCSC for either the anode or the cathode. A two-layer mesh with the layers insulated from one another may serve as the electrical conduction networks for both the anode and the cathode.

In the cases of the flexible substrate being a fabric, a net, or a mesh, it is anticipated that the fibers or other fabric, net or mesh material in the flexible substrate may themselves be electrical conductors; one set of fibers being the electrical conducting network for the cathode and another set the electrical conducting network for the anode. It is anticipated that the individual conducting fibers be extensible such as using iStretch wires from Minnesota Wire, 1835 Energy Park Dr., St Paul, Minn. 55108. In such a case that is intended to be exemplary and not limiting, the individual conducting fibers would have the full electrical conductivity of copper wire but is extensible to 30% of its length between attachment points to SCCs.

As described herein, an array of individual SCCs may be attached to the flexible substrate. The substrate serves to maintain the relative positions of SCCs one to another consistent with the mechanical properties of the substrate. The SCCs are attached to the substrate by any of several means. The means described in this disclosure are intended to be exemplary and are not intended to be limiting in any way.

In the case of the substrate being a fabric or a film, an SCC may be attached to the substrate by an adhesive such as an epoxy, a silicon rubber, a polyurethane. The specific adhesive choices illustrated by epoxy, silicon rubber, or polyurethane are not limiting and any adhesive suitable for a final implementation is envisaged by the invention. In such cases the SCC may be a completely assembled and functioning solar cell requiring only to be attached to the substrate and/or to establish the overall MCSC structure by being connected to other SCCs in the MCSC by the conducting network that would establish the parallel electrical circuit. Alternatively, the SCC may be in a partial state of completed assembly with its final assembly completed after or during the attachment of the SCC to the substrate and/or to the conducting network.

In the special cases of the substrate being a woven or unwoven fabric, a net, or a mesh, the SCC may be made of an appropriate material such as a polymer resin that the SCC is caused to partially penetrate the substrate thereby sterically interlocking the SCC to the substrate. In this manner, an exceptionally strong bond between the SCC and the substrate is formed that maintains mechanical integrity throughout bending and stretching motions and stresses. It is further envisaged, but not in limiting fashion, that the adhesive, resin, or other such material may be part of the SCC structure itself and that such attachment of the SCC to the substrate may be performed prior to the final assembly of the SCC or the SCU contained therein.

In the special cases of the substrate being a net or mesh of conductive fibers that will itself form the conducting electrical network, both a mechanical connection and one or more electrical connections must be made between the SCC and the substrate. The SCC has both a cathode and an anode. The cathode and anode of each SCC must be electrically connected to the cathodes and anodes of other SCCs in the manner that delivers the electrical voltage and amperage required by the assembly in its end use. Other electrical components such as diodes are also included in the circuit as required by the end application. The electrical connections may be solder, wire bonds, conductive adhesives or any other type of electrical connection suitable to the applications of the final assembly.

In instances where such electrical connections may not be tolerant of stresses associated with bending or stretching motions caused by flexing of the overall MCSC, stress relief structures in addition to the electrical connections may also need to be provided. In such cases, it is envisaged that the attachment of the SCC to the substrate will involve, but not be limited to, adhesives or resins that penetrate or partially penetrate the mesh or net. It is further envisaged, but not in limiting fashion, that the adhesive, resin, or other such material may be part of the SCC structure itself and that such attachment of the SCC to the substrate may be performed prior to the final assembly of the SCC or the SCU contained therein.

The SCU that is contained within the SCC that, in turn, is attached to the substrate and networked both mechanically and electrically to other SCCs to form the MCSC may be, but is not limited to, a silicon wafer, a perovskite solar cell, or any other suitable solar cell construction compatible to the overall specification for the MCSC assembly. For example, in the SCC 100 of FIGS. 1a and 1b, silicon wafer 101 constitutes a SCU. The SCCs in the MCSC need not all be identical to one another. They may differ in size, shape, and in the type of SCU contained therein in any combination suitable for the final application of the MCSC. Each SCC is not limited to containing only a single type SCU within the encapsulation. Hybrid SCU constructions involving, for example, perovskite and silicon wafer SCU components are known. The disclosure is not limited to just the combination of perovskite and silicon wafer hybrid structure.

To ensure long-term function and reliability, an SCU within an SCC should be protected from environmental elements such as humidity and oxygen and be protected from UV radiation while still being exposed to visible radiation. Indeed, the major issues that prevent perovskite solar cells from being commercially viable are their stabilities against humidity, oxygen and UV radiation and temperature. One such means of encapsulation is shown in FIGS. 1a and 1b. Example MCSC of the disclosure may solve some or all four of these problems.

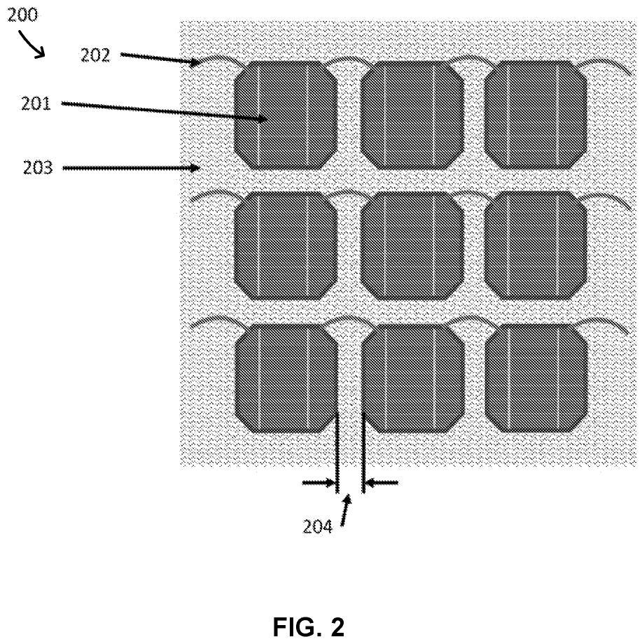

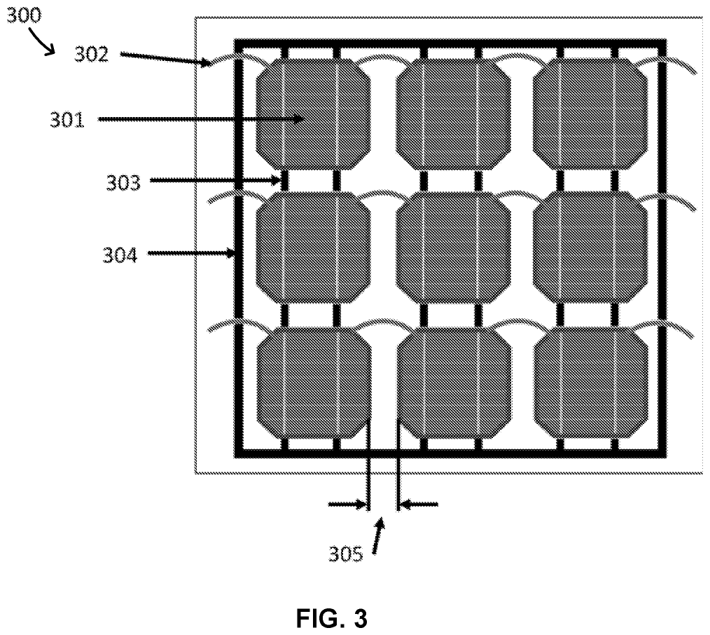

FIG. 2 is a conceptual diagram illustrating an example flexible MCSC assembly 200 in accordance with some examples of the disclosure. As shown in FIG. 2, flexible MCSC assembly 200 includes a plurality of SCCs 201 (only one SCC is labelled for clarity). SCCs 201 may be the same or similar to that shown and described as SCC 100 in FIGS. 1a and 1b. For example, SCCs 201 may include are silicon wafers individually encapsulated by a polymeric resin that isolates the silicon wafer from the environment but permits electrical conductors 202 to extend from the anode and the cathode of the silicon wafer of SCC 201 to outside the encapsulating material (e.g., material 103 of FIGS. 1a and 1b). Each silicon wafer SCC 201 may be attached to a flexible substrate 203 by a suitable adhesive or other appropriate attachment mechanism such as staples, rivets, or loops, with sufficient space 204 between adjacent individual SCC units 201 to permit the MCSC assembly 200 to conform to a planar or non-planar surface upon which assembly 200 is placed. For 6 inch, square, SCC units, an example space is about 0.5 inch to 1 inch to give the overall MCSC unit an overall empty space or porosity of between 0.1 and 0.3. Such a spacing will dramatically reduce wind loading effects on MCSC panels with the 0.3 porosity giving a much greater reduction in wind loading than a spacing of 0.1. The wind pressure loss coefficient decreases with the inverse square of the porosity. A space of about 2 inches or more on such 6 inch, square SCC units, allows the MCSC assembly to be folded over upon itself if the SCC units are mounted on a flexible substrate 203.

The specific examples of the attachment mechanisms described herein are not limiting as any attachment required by the end use of the MSCS 200 is envisaged by the disclosure. In some cases, the spaces 204 between individual SCCs 201 may be sufficiently large to permit the folding of individual SCCs 201 over one another. Spaces 204 in the two dimensions need not be the same nor uniform throughout the MCSC assembly 200. Such an assembly will conform to surfaces with curvature limited by the dimension of the SCC. Typical sizes of such SCC using commercially available silicon wafers are about five to about six inches and are roughly square, but the disclosure is not limited to these specific dimensions. The polymeric resin may be an epoxy such as EPON 828 combined with an aliphatic amine hardener that renders the resultant epoxy encapsulant resistant to UV degradation. EPON is a trademark of Hexion Inc., Columbus, Ohio. Such epoxy resins are well-known to be resistant to penetration by oxygen, water, acids and bases and exhibit good weathering characteristics. The choice of such an epoxy is exemplary only and is not limiting. Other choices of encapsulating structures are envisaged such as the use of PTFE or ETFE films either alone or in combination with platinum catalyst silicone rubbers. The advantage of such encapsulating materials over EVA that is used in other silicon wafer solar panels is that no acetic acid is formed in the case of some amount of UV degradation. The acetic acid, even in trace amounts, corrodes electrical connections to the silicon wafer. The electrical conductors from the SCC cathode and anode are electrically insulated from one another and connected to conductors from other SCC units in the MCSC assembly to form an electrical circuit appropriate to the amperage and voltage that is expected to be drawn from the overall MCSC assembly. The electrical power drawn from the MCSC assembly can be used to power equipment, instruments, heaters, or other electrical device in the vicinity of the MCSC; can be stored in a battery or fuel cell for use when the sun does not shine or when the power from the MCSC is not optimum for an intended purpose; or can be delivered to an electrical power grid.

A second, preferred embodiment based on the example assembly 200 shown in FIG. 2 is to use as a flexible substrate 203 a suitable SUPERFABRIC®, a product of Higher Dimension Materials, Oakdale, Minn., USA, as the flexible substrate 203. SUPERFABRIC® is an abrasion resistant, cut resistant, stain resistant fabric that gives the resultant flexible MCSC considerable durability in and of its own right while preserving desired flexibility. The choice of SUPERFABRIC® as a flexible substrate is not limiting. Any substrate material including woven or non-woven fabrics, nets, screens, or meshes of suitable materials may be used instead of, or in addition to, one another or to SUPERFABRIC®. The flexible substrate may be a single layer or be multiple layers depending on the requirements of the final application.

A specific example of use for the preferred embodiment (or other embodiment described herein) is as a roofing material. In this instance, the choice of SUPERFABRIC® as the flexible substrate 203 would be chosen to be waterproof so that the MCSC assembly may serve the dual function of shingles and as solar electricity generation. The SUPERFABRIC® substrate material is abrasion resistant and sufficiently durable to permit workers to walk on the SUPERFABRIC® substrate 203 without damaging it. SUPERFABRIC® is stain resistant so the roofing material will maintain its color and aesthetic appeal for many years even though exposed to weather and pollutants. The SCC units 201 in such a roofing application may use, but is not limited to, an epoxy resin such as EPON 828 combined with an aliphatic amine hardener that renders the resultant epoxy encapsulant resistant to UV degradation. Such encapsulations can be made sufficiently strong and robust to withstand workers walking on them or moving equipment over them without damaging the SCC unit. Major advantages of using the preferred embodiment as a roofing material over and against traditional solar modules that are mounted on roofs are that the MCSC assembly 200 may be lighter in weight and, since the MCSC is mounted flush to the roof, subjects the roof to much less wind loading. Traditional solar panels mounted on roofs often require major structural changes to the roof to support the weight and the wind loading. In many regions such roof installations must withstand the wind load of a 100 mile per hour wind.

FIG. 3 is a conceptual diagram illustrating another example MCSC assembly 300 in accordance with some examples of the disclosure. As illustrated in FIG. 3, the MCSC assembly 300 includes SCCs 301, e.g., as described in FIGS. 1a and 1b as SCC 100, which may be silicon wafers individually encapsulated by a polymeric resin that isolates the silicon wafer from the environment but permits electrical conductors 302 to extend from the anode and the cathode of the silicon wafer to outside the encapsulating material. Each silicon wafer SCC 301 is attached to a substrate that is a porous frame, lattice, or scaffold. FIG. 3 shows a lattice or scaffold constructed of support bars or rods 303 connected to a circumferential frame 304 by a suitable adhesive or other appropriate attachment mechanism such as staples, rivets, or loops, with sufficient space 305 between adjacent individual SCC units 301 to permit the MCSC assembly 300 to permit air and sunlight to pass through the MCSC assembly 300. The specific examples of the attachment mechanisms are not limiting as any attachment required by the end use of the MSCS is envisaged by the disclosure. The disclosure envisages that the materials used to form the scaffold, frame, or lattice may be the same or different than other materials used in the frame, scaffold, or lattice. The disclosure also envisages that the frame, scaffold, and lattice elements may by themselves or in concert with one another establish the electrical circuit required by the end application of the MCSC.

In some examples, there are many advantages of the embodiment of the disclosure shown in FIG. 3 over and against traditional silicon wafer solar cells.

For example, the lattice or scaffold structure 300 may permit a rigid panel with dramatically reduced weight and wind loading. Since air passes unimpeded through the spaces between the SCC units 301, wind loading is dramatically reduced. The spaces 305 form a porosity for the overall panel. Porosity is the fractional area of the panel that does not obstruct sunlight or air passage. Even a small amount of porosity strongly affects the wind load. Studies on the wind load of porous panels dates from the second world war when radar antennae were first being installed to the present day for porous structures that can be used as animal shelters that provide animals with shade while still providing ventilation. Such structures are especially useful in geographies such as Australia where livestock is commonly located many miles from ordinary farm structures. Those studies show that the wind load factor decreases with the square of the porosity. The example of FIG. 3 may allow such structures to produce their own local electricity. That electricity can be used to aid ventilation or to power transceivers that relay animal health metrics back to a farmstead. Livestock animals commonly have embedded sensors that monitor temperature, blood oxygen, dehydration, and a number of other health factors. That information is generally transmitted by RFID or similar technologies to a receiver that is local to the animals. That receiver needs to transmit the data to the farmstead many miles away and that requires substantial power. That power can be conveniently provided by the example of FIG. 3 by incorporating solar energy collection into the porous structure that is otherwise used to shelter the animals. The porosity retains the shading, ventilation, and reduced wind loading required by such structures while at the same time allows local solar electricity generation.

Another advantage of the porous structure 300 of the third example is that it may allow air cooling of the individual SCC units 301. Heat is an enemy of silicon wafer solar cells and electrical generation efficiency declines dramatically with increasing temperature. The porous structure 300 permits cooling of the SCC units as air is allowed to completely surround and flow between the SCC units.

Another advantage of the porous structure 300 of the third example is that it may allow sunlight and rain to penetrate through the panel to the surface beneath it. The land beneath traditional solar farms may be an environmental wasteland. Nothing useful can grow under the panels because little sunlight or moisture reaches the ground beneath. The shade, however, can foster the growth of harmful molds that are foreign to the regions of the solar farms. Such molds have no natural enemies in those regions and are not controlled by natural means.

The specific example of a frame with a lattice or scaffold structure to produce a panel with porosity is not limiting. The disclosure envisages that the MCSC assembly be mounted on a porous screen or porous mesh with the desired degree of porosity for air, sunlight, and moisture passage. Such structures can also be flexible thereby enabling such structures as animal shelters to be tent-like greatly increasing the convenience of setting up and moving such structures.

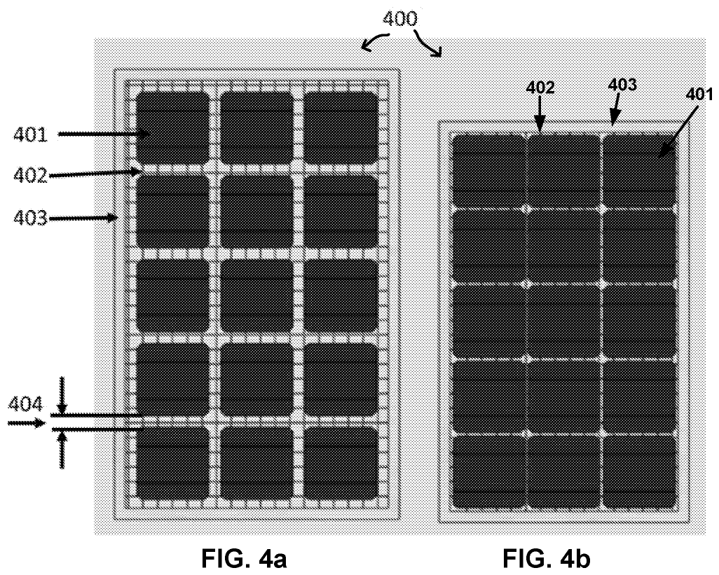

Examples of the MCSC 400 mounted on a mesh, screen or net are shown in FIGS. 4a and 4b. In FIGS. 4a and 4b, the individual SCC units 401 are affixed to a screen, mesh, or net 402 which is supported by a frame 403. The spaces 404 on such a screen, mesh, or net type of substrate are infinitely adjustable to deliver the porosity required in a final application.

In the MCSC 400 the material of the mesh, screen, or net can be any suitable material such as a yarn, or fiber that can be either a natural substance such as cotton or wool or a man-made material such as nylon, polyester, or Kevlar. The choice of material for the yarn or fiber is not limiting. In other instances, the mesh, net, or screen may be made from a metal such as aluminum, titanium, stainless steel, or an advanced composite such as carbon fiber. The specific choice of material for the screen, net or mesh is not limiting as any choice of material suitable for the final application is envisaged by the disclosure. The frame material may be aluminum, stainless steel, titanium, carbon fiber or any other material suitable for the construction of the frame. The choice of a specific material for the frame is not limiting. The space 404 shown in FIG. 4a gives a porosity of approximately 0.3. The porosity in the example of FIG. 4b, which is illustrated in size relative to FIG. 4b, is substantially smaller. The choice of spacing is not limiting and is made on the basis of wind loading that is expected in the final implementation of the MCSC assembly.

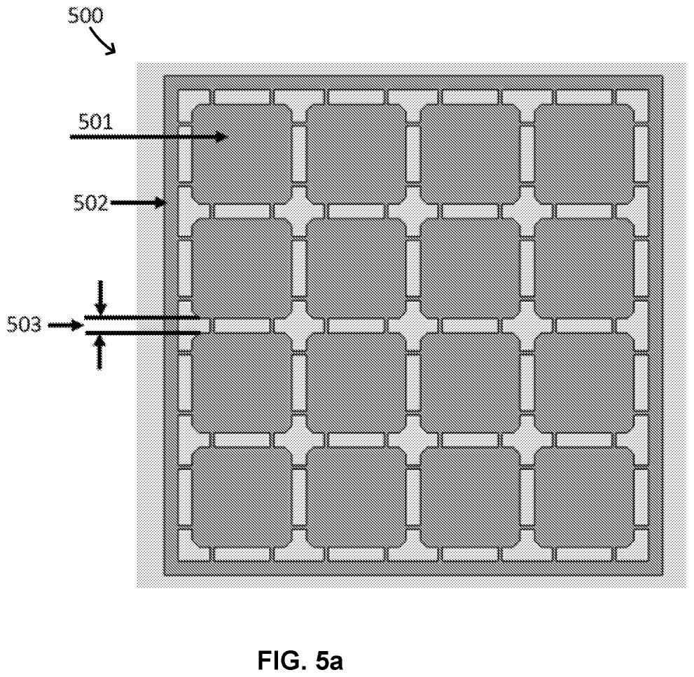

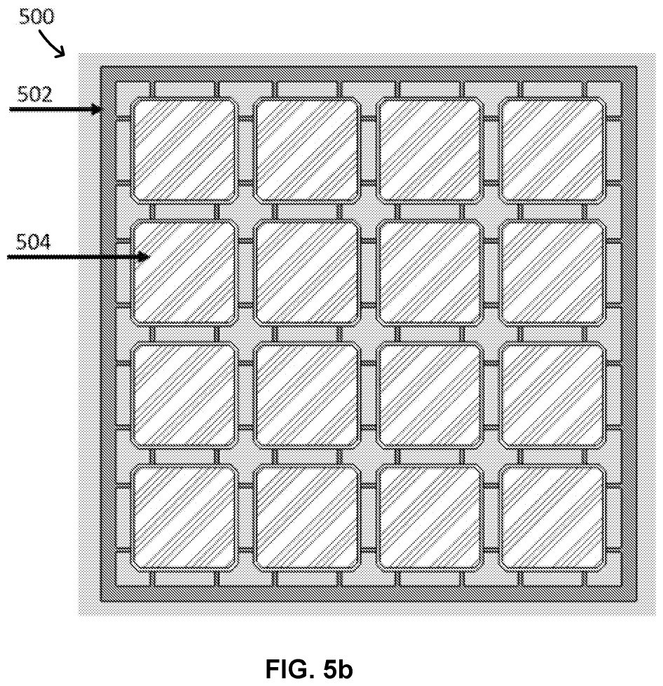

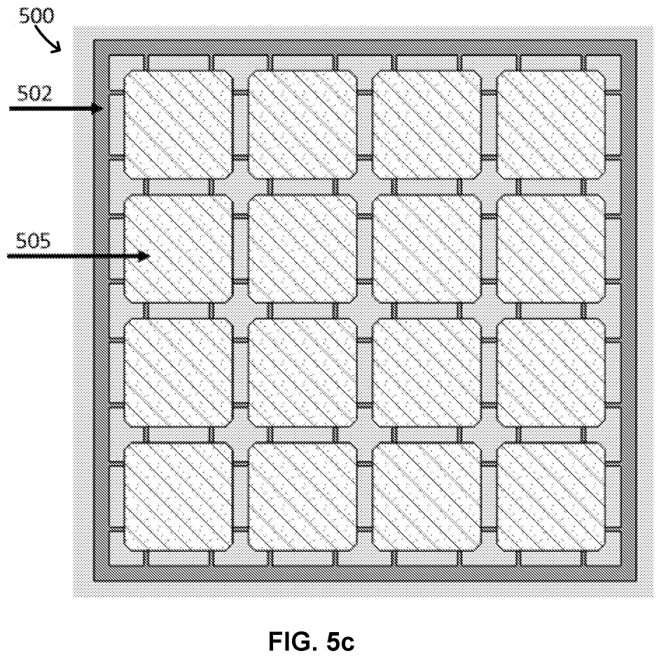

As mentioned in reference to the SCC 100 shown in FIG. 1, the encapsulant may be comprised of more than a single layer and such layers need not necessarily be of the same composition as one another. This freedom allows another preferred embodiment of the disclosure. FIG. 5a is a conceptual diagram illustrating an example MCSC unit 500 wherein the bottom portion of the encapsulant of the SCC 501 is incorporated with a frame and support members as a single unit 502. For example, the bottom portion of the encapsulant may be integrally formed with the frame and support member portion (e.g., as single piece). The spaces 503 between adjacent bottom portions of the encapsulant and between the bottom portions of the encapsulant and the perimeter frame are open spaces (porosity) that allow air, moisture, and sunlight to flow between and around the individual units in the MCSC 500. In this way, a strong, lightweight single component structure can provide both support for the overall MCSC assembly and provide the base for the encapsulation of the individual SCUs. Typical materials for the frame, support members and bottom layer of encapsulant is an epoxy, epoxy composite, fiberglass composite, or carbon fiber. The disclosure envisages that other materials may also be used so the choices of epoxy, epoxy composite, fiberglass composite, or carbon fiber are not limiting. The choice of materials for the frame, the support members, and the bottom layer of the encapsulant may be the same as one another or may be different.

FIG. 5b is a conceptual diagram illustrating the single unit 502 of FIG. 5a with SCU units installed on the encapsulant bases of the SCC. The illustration shows silicon wafers 504 as the choice for the SCU, but the invention is not limited by this choice. SCU comprised of perovskite materials, CdTe materials, or CIGS materials or other solar cell materials may also be used.

FIG. 5c is a conceptual diagram illustrating the single unit 502 of FIG. 5b with a top layer transparent encapsulant 505 applied over the individual SCU units located on the encapsulant bases. This top layer must be transparent to visible light to permit sunlight to impinge on the SCU contained within the encapsulant. The transparent encapsulant 505 may itself be a layered structure. Typical materials for the transparent encapsulant 505 include epoxy, ETFE film, or PTFE film, but the invention is not limited by these specific choices of materials as other materials may also prove beneficial. Examples of layered structures for the transparent encapsulant 505 include but are not limited to silicon rubber covered by epoxy, silicon rubber covered by ETFE film, or silicon rubber covered by PTFE film.

As illustrated in FIGS. 5a-5c, the bottom portion of the encapsulant may be integrally formed with the frame and support member portion (e.g., as single piece) rather than requiring SCCs that have been pre-formed and subsequently attached to the frame and support members. The individual SCU units may be placed on the bottom portion of the encapsulant (e.g., as shown in FIG. 5b) and then encapsulated on top and sides (e.g., as shown in FIG. 5c).

Regardless of the means of providing porosity in such a panel, whether it be by mounting a MCSC assembly on a frame, scaffold, lattice, mesh, or screen, or incorporating porosity as spaces in a unified structure that provides both structural support and a base for encapsulants, the disclosure envisages providing a porosity in the 0.2 to 0.4 range, though such a range is not limiting. A greater or lesser porosity may be desired for a specific application. A traditional solar panel has essentially no porosity. An increase in porosity from 0.1 to 0.4 would reduce the wind pressure loss coefficient by a factor of 16. Using porous MCSC assemblies on structures subjected to strong winds can dramatically improve the durability of such structures while still producing the requisite amount of electricity.

Various examples have been described. These and other examples are within the scope of the following claims.

1. A solar cell assembly comprising:
at least one substrate including a top surface;
a plurality of solar cell capsules affixed to the top surface of the at least one substrate such that a plurality of continuous gaps is defined between adjacent solar cell capsules of the plurality of solar cell capsules, wherein each of solar cell capsules of the plurality of solar cell capsules includes one or more solar cell units, wherein the solar cell units are contained in an encapsulant to protect the solar cell units from one or more of water and oxygen molecules, atmospheric pollutants, dirt, soot, and strong chemicals or by mechanical abrasion, impact, UV light, and temperature; and
a plurality of electrical conductors interconnecting the solar cell capsules one to another to form an electrical circuit.

2-23. (canceled)

24. A solar cell assembly comprising:
a rigid frame defining an array of connected support structures with open spaces between respective support structures of the rigid frame, the open spaces being configured to allow air and sunlight to pass through the rigid frame; and
a plurality of solar cell capsules separated from each adjacent solar cell capsule of the plurality of solar cell capsules by a gap aligned with the open spaces between respective support structures, wherein each solar cell capsule of the plurality of solar cell capsules includes at least one photovoltaic solar cell encapsulated by with a polymeric material, the polymeric material protecting the at least one photovoltaic solar cell solar cell against damage from water molecules, oxygen molecules, and chemicals, and
wherein the at least one photovoltaic solar cell of each of the plurality of solar cells are electrically connected to each other to establish an electric circuit for generation of electricity from light.

25. The assembly of claim 24, wherein an open porosity of the assembly defined by the open spaces of the frame and the gaps between the plurality of solar cell capsules is about 10% to about 40% for the assembly.

26. The assembly of claim 24, wherein the rigid frame is made of at least one of a polymeric material, a glass, a metal, or combinations thereof.

27. The assembly of claim 24, wherein the rigid frame is made of an epoxy, an epoxy composite, fiberglass composite, a carbon fiber composite, or combinations thereof.

28. The assembly of claim 24, wherein all of the at least one photovoltaic solar cell of all of the plurality of solar cells are electrically connected to each other to establish an electric circuit for generation of electricity from light.

29. The assembly of claim 28, wherein the light comprises sunlight.

30. The assembly of claim 24, wherein the at least one photovoltaic solar cell is a silicon wafer solar cell.

31. The assembly of claim 24, wherein the at least one photovoltaic solar cell is at least one perovskite solar cell.

32. The assembly of claim 24, wherein the at least one photovoltaic solar cell is at least one Copper Indium Gallium Diselenide solar cell.

33. The assembly of claim 24, wherein the at least one photovoltaic solar cell is at least one CdTe solar cell.

34. The assembly of claim 24, wherein the polymeric material encapsulating the at least one photovoltaic solar cell comprises at least one of an epoxy, a silicon rubber covered by epoxy, a silicon rubber sandwiched in an ETFE film, or a silicon rubber sandwiched in an PTFE film.
